(19) United States
(12) Patent Application Publication
(10) Pub. No.: US 2024/0414854 A1
(43) Pub. Date: Dec. 12, 2024

(54) METHOD, SYSTEM, HOUSING, AND PRINTED CIRCUIT BOARD FOR PRODUCING A ROTATIONAL ANGLE SENSOR UNIT

(71) Applicant: HELLA GmbH & Co. KGaA, Lippstadt (DE)

(72) Inventor: Keramettin SEVEN, Lippstadt (DE)

(73) Assignee: HELLA GmbH & Co. KGaA, Lippstadt (DE)

(21) Appl. No.: 18/808,068

(22) Filed: Aug. 18, 2024

Related U.S. Application Data
(63) Continuation of application No. PCT/EP2023/052406, filed on Feb. 1, 2023.

(30) Foreign Application Priority Data
Feb. 17, 2022 (DE) 10 2022 103 725.8

(51) Int. Cl. H05K 5/00; G01D 5/20

(52) U.S. Cl. CPC H05K 5/0026; G01D 5/2066

(57) ABSTRACT

A method for producing a rotational angle sensor unit comprising a housing unit, which has a housing that defines a housing volume. A rotor is at least partly positioned in the housing volume, and a gearwheel adapted to be rotated by the rotor. A printed circuit board is positioned in the housing volume. The method has the following steps: providing an aligning structure, positioning the aligning structure on the housing unit, and positioning the printed circuit board in the housing volume using a positioning unit. The positioning unit is moved relative to the position of the aligning structure on the housing unit in order to position the printed circuit board in a specified position relative to the rotor. A system, a housing, and a printed circuit board are also provided for producing the rotational angle sensor unit.

This nonprovisional application is a continuation of International Application No. PCT/EP2023/052406, which was filed on Feb. 1, 2023, and which claims priority to German Patent Application No. 10 2022 103 725.8, which was filed in Germany on Feb. 17, 2022, and which are both herein incorporated by reference.

### BACKGROUND OF THE INVENTION

### Field of the Invention

The present invention relates to a method, a system, a housing, and a printed circuit board for producing a rotational angle sensor unit. The invention relates in particular to a method for producing a rotational angle sensor for determine a relative angular position of a rotor with respect to a reference position of a stator, wherein the stator is positioned in a housing on a printed circuit board with electrical and/or electronic components.

### Description of the Background Art

Inductive torque sensors are generally known in the prior art. They are used in motor vehicles, for example, in order to detect torques such as steering torques. This is becoming increasingly necessary because electric motor driven servo devices are being used more and more for power steering. These devices require a magnitude of the steering torque for control. Steering torques are detectable as difference angles in a steering column via a shaft and, in particular, via a torsion bar, and are calculated therefrom. For this purpose, the twists at the ends of the torsion bar are determined as signals via a suitable arrangement and transmitted to analysis units. The difference angles that are caused by the torsion can be determined independently of a position of the steering wheel. Furthermore, it is important, for example for driver assistance systems, to know the position of the steering wheel. For this purpose, a steering angle of the steering wheel is determined via a rotational angle sensor unit.

Generic rotational angle sensor units are described in, for example, EP 2 870 033 B1, which corresponds to US 2015/0168140, which is incorporated herein by reference.

For as accurate a determination of the steering angle as possible, it is necessary that the position of the printed circuit board in the housing relative to the rotor remains as stable as possible radially and axially. A loss of the relative position causes an incorrect or undetectable sensor signal, which can lead to a safety-relevant fault.

In order to achieve the requisite sensor performance, the central axis of a circuit board through opening must be positioned as coaxially to the central axis of the rotor as possible. This represents a challenge, in particular because positioning the printed circuit board directly on the rotor is not possible on account of a mounting of the printed circuit board in the housing with play.

### SUMMARY OF THE INVENTION

It is therefore an object of the present invention to at least partially take into account the problems described above. In particular, it is an object of the present invention to create an approach for an improved assembly of a rotational angle sensor unit, in particular with regard to the most precise possible positioning of the printed circuit board relative to the housing and to the rotor.

The above object is attained by a method, a system, a housing, and a printed circuit board. Of course, features that are described in connection with the method also apply in connection with the system according to the invention, the housing according to the invention, the printed circuit board according to the invention, and vice versa in each case, so mutual reference is and/or can always be made with regard to the disclosure of the individual aspects of the invention.

According to a first aspect of the present invention, a method for producing a rotational angle sensor unit is proposed. The rotational angle sensor unit has a housing unit with a housing that defines a housing volume, a rotor that is at least partly positioned in the housing volume, and a gearwheel that can be rotated by the rotor. The rotational angle sensor unit additionally has a printed circuit board that is positioned in the housing volume. The method has the following steps: providing an aligning structure; positioning the aligning structure on the housing unit or the housing unit on the aligning structure; and positioning the printed circuit board in the housing volume via a positioning unit, wherein the positioning unit is moved with respect to the position of the aligning structure positioned on the housing unit in order to position the printed circuit board in a predefined position relative to the rotor.

It was found that an especially accurate positioning of the printed circuit board in the housing or in the housing volume can be made possible in a simple manner by the means that the printed circuit board is not aligned directly to the housing during installation, but instead to an additional aligning structure positioned on the housing. The aligning structure can accordingly be understood as a component that is provided separately from the housing and is removed again from the housing for completion of the rotational angle sensor unit.

Via the aligning structure, a housing alignment axis, in particular a central axis through a housing through opening for the passage of the rotor and a shaft, and a circuit board alignment axis, in particular a central axis through a circuit board through opening for the passage of the rotor and the shaft, can be aligned to one another in a simple and reliable manner, in particular can be aligned coaxially to one another to the greatest degree possible. As a result, a correspondingly accurate positioning of the printed circuit board in the housing volume can be achieved.

The printed circuit board can be a circuit board or a generic PCB. The printed circuit board can be positioned in the housing volume with or without a stator and/or other electrical and/or electronic components mounted thereon in advance. The housing can be understood to be an open housing shell that can be closed with a housing cover in the process of producing the rotational angle sensor unit. Once the housing is closed, it of course continues to have at least one overall-housing through-opening, through which at least one shaft and the rotor or at least one rotor can extend.

The rotor can be a component unit with a rotor sleeve, an annular conductor section on an end face, and a connector for connecting the rotor rim to the rotor sleeve. The end-face conductor section can also be designed to be or to become integral or a single piece with the rotor sleeve, however. The gearwheel can be understood to be a generic gear with a gear region and a flange region, wherein the flange region can extend further outward in a radial direction than the gear region.

At least one part of the aligning structure can be sleeve-like in design, and be positioned on the housing and/or on the housing unit coaxially to the housing through opening. The aligning structure is preferably positioned on the housing unit in a frictional and/or interlocking manner, in particular so as to be nondestructively removable. In addition, the positioning of the aligning structure preferably is accomplished directly, which is to say without additional holders.

The positioning unit can be a gripper and/or an appropriately automatable robot arm. Thus, the positioning unit can grip and/or hold the printed circuit board for positioning the printed circuit board in the housing volume and subsequently release it at the desired position in the housing volume.

The aligning structure can have an alignment guide and the positioning unit can have a positioning guide, wherein the positioning guide is guided along the alignment guide in order to move the positioning unit with respect to the position of the aligning structure. Via the alignment guide and the positioning guide, the printed circuit board can be guided not only computationally or in an appropriate computer-based manner, but also mechanically, and thus moved to the desired position with corresponding reliability. Accordingly, the desired positioning can be carried out especially simply, quickly, and reliably via the alignment guide and the positioning guide.

Furthermore, it is possible that the alignment guide and the positioning guide are each moved through a rotor opening of the rotor and/or a projection of the rotor opening to guide the positioning guide along the alignment guide. Consequently, no additional installation space need be provided for the alignment guide and the positioning guide in order to carry out the method. The method can therefore be carried out in an especially flexible and space-saving manner. The projection of the rotor opening can be understood to mean an extension of the rotor opening in an axial direction of the rotor opening. Hence, the alignment guide and the positioning guide need not both extend into the rotor opening. It suffices, for example, when one of the two guides extends into and beyond the rotor opening and the other guide is configured in accordance with the invention to contact this guide for the desired positioning of the printed circuit board. The alignment guide and the positioning guide are preferably guided on one another along a rotor axis of the rotor opening and/or along a coaxial housing axis of a housing through opening. The alignment guide and the positioning guide can each be designed to be sleeve-like and/or for a telescoping guidance with one sliding inside the other.

Moreover, the aligning structure can be positioned on the housing unit via a press fit. As result, the aligning structure can be positioned on the housing unit in an especially simple way. A subsequent removal of the alignment unit from the housing unit is also possible in this case. Additional holding and/or fastening elements can be dispensed with.

In addition, during the positioning of the printed circuit board in the housing volume, the housing can be held in a predefined position by a holding device attached to the housing. In other words, the housing is not held by the aligning structure, but instead by a or the separate holding device that is positioned on a position on the housing distant from the aligning structure and/or on the housing unit on the housing. The assembly or the production of the rotational angle sensor unit can be carried out especially simply via the holding device. The holding device can have a clamping device or be designed as a clamping device for a clamped attachment of the housing in a predefined position during the production of the rotational angle sensor unit. The holding can accordingly be understood to be an attaching and/or securing of the housing in a predefined position.

The gearwheel can have a gear region and a flange region, wherein the aligning structure is positioned on the flange region. This means that the aligning structure is not positioned on the housing, or not only on the housing, but instead is at least also additionally positioned on the flange region or on the gear wheel. With the gearwheel, a hard and deformation-free stop is provided, via which there is no danger of damage or destruction of the housing unit, even in the case of a press fit of the aligning structure on the housing unit.

The housing unit can have a clamp and the printed circuit board can have a mating clamp, wherein the printed circuit board is positioned in the housing volume via a clamped connection between the clamp and the mating clamp. The clamp and the mating clamp are designed to be separate from, and spaced apart from, the alignment guide and the positioning guide. Consequently, the clamped connection preferably is produced with play. The printed circuit board can be positioned at the desired location in the housing volume quickly and simply via the clamped connection.

The clamped connection between the clamp and the mating clamp can be produced while the positioning guide is guided along the alignment guide in order to position the printed circuit board in the housing volume. As a result, the printed circuit board is mechanically guided and/or aligned via a guide between the alignment guide and the positioning guide as well as between the clamp and the mating clamp during the desired positioning of the printed circuit board in the housing volume. In this way, the printed circuit board can be positioned at the desired location in the housing volume especially reliably.

A further aspect of the present invention relates to a system for producing a rotational angle sensor unit via a method as described in detail hereinabove. For this purpose, the system has the aligning structure and the positioning unit, wherein the aligning structure has the alignment guide and the positioning unit has the positioning guide in order to move the positioning unit along the alignment guide with respect to the position of the aligning structure. As a result, the system according to the invention offers the same advantages as have been described in detail with respect to the method according to the invention. The system can be understood to be, in particular, an industrial facility or a part of an industrial facility for manufacturing a rotational angle sensor unit characterized by the functional components according to the invention. The aligning structure can be considered a separate component that is used for the production process but does not remain on the final rotational angle sensor unit.

A system according to the invention can have a holding device for holding the housing during the positioning of the printed circuit board in a predefined position. As described hereinabove, the holding device can be configured and designed in the form of, in particular, a clamping device for producing a clamped connection between the holding device and the housing. As a result, the housing can be held and/or secured in the desired position especially simply during the process of producing the rotational angle sensor unit.

According to a further aspect of the present invention, a housing can be provided for producing a rotational angle sensor unit via a method as described hereinabove. The housing has a clamp for producing a clamped connection with a mating clamp of the printed circuit board. As a result, the housing according to the invention also offers at least a portion of the above-described advantages. The housing can be understood to be an open housing shell, which can be closed with a housing cover. The housing has at least one housing through opening, in which at least one rotor and/or at least one shaft can be positioned. The housing can additionally have an alignment receptacle for receiving the aligning structure, in particular via a press fit. In order to receive the aligning structure, the alignment receptacle can be designed to be ring-shaped and/or have a circular wall structure.

In a housing according to the invention, the clamp can have at least one clamping peg for producing a clamped connection with a corresponding clamping opening of the mating clamp of the printed circuit board and at least one clamping recess for producing a clamped connection with a corresponding clamping projection. As a result, the desired clamped connection can be produced especially simply and reliably. The at least one clamping peg preferably extends along a rotor axis and/or housing axis that extends through the above-described housing through opening.

It can furthermore be advantageous in a housing according to the invention when lateral crush ribs project from an outer circumferential surface of the clamping peg for the purpose of producing the clamped connection with the clamping opening of the mating clamp. Such crush ribs have proven to be a simple but nevertheless reliably functioning means for producing the desired clamped connection. The crush ribs are preferably arranged radially around the respective clamping peg. The crush ribs preferably extend orthogonally to the longitudinal direction and/or direction of extent of the clamping peg and/or pegs.

The housing according to the invention or the housing shell can be one-piece and/or monolithic in design, moreover. As a result, the housing including the clamping recess, the clamping pegs, and the crush ribs can be provided especially simply, especially with regard to the concrete manufacturing process and/or the associated logistics.

A further aspect of the invention relates to a printed circuit board for producing a rotational angle sensor unit via a method as described hereinabove using a housing as described hereinabove. The printed circuit board has a mating clamp with at least one clamping opening and a clamping projection, wherein the clamping projection extends from an edge region of the printed circuit board orthogonally or essentially orthogonally to an opening direction of the at least one clamping opening. As a result, the printed circuit board according to the invention also offers the above-described advantages.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a printed circuit board;

FIG. 2 shows a perspective view of a rotational angle sensor unit during assembly;

FIG. 3 shows a detail view of a housing for the rotational angle sensor unit;

FIG. 4 shows a perspective view of a rotational angle sensor unit during assembly;

FIG. 5 shows a detail view of the printed circuit board clamped in the housing;

FIG. 6 shows an exploded view of the components relevant to the invention for producing the rotational angle sensor unit;

FIG. 7 shows a sectional side view for explaining a method for producing the rotational angle sensor unit; and

FIG. 8 shows a flowchart for explaining a method for producing the rotational angle sensor unit.

### DETAILED DESCRIPTION

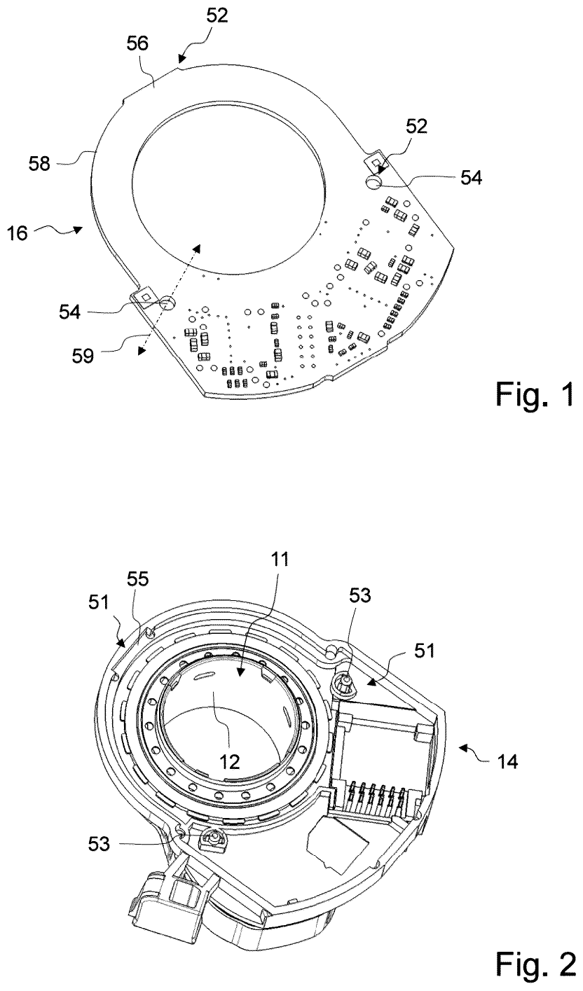

FIG. 1 shows a printed circuit board 16 with a mating clamp 52 that includes two clamping openings 54 and a clamping projection 56. The clamping projection 56 extends from one edge region 58 of the printed circuit board 16 orthogonally to an opening direction 59 of the at least one clamping opening 54. The clamping openings 54 are designed in the form of through holes.

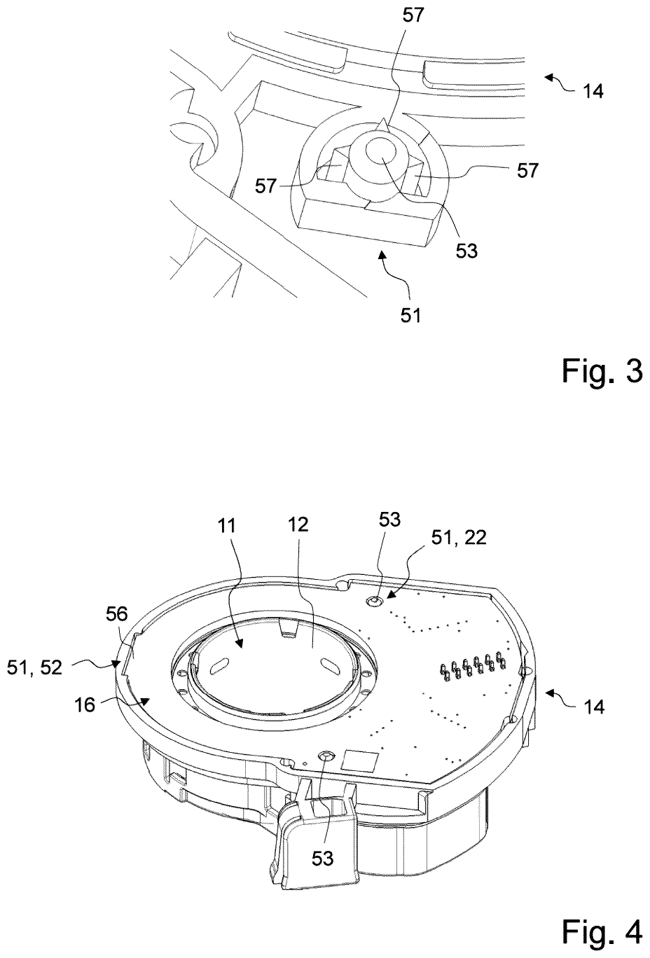

FIG. 2 shows a housing unit with a housing 14 or an open housing shell that is used for producing a rotational angle sensor unit. The housing unit further includes a rotor 11, which is positioned on the housing 14 or in a housing through opening. The housing 14 shown has a clamp 51 for producing a clamped connection with the mating clamp 52 shown in FIG. 1 of the printed circuit board 16. In addition, the clamp 51 includes a clamping recess 55 for producing a clamped connection with the corresponding clamping projection 56. Lateral crush ribs 57 project from an outer circumferential surface of each of the clamping pegs 53 for the purpose of producing the clamped connection with the associated clamping opening 54 of the mating clamp 52. The housing 14 or the housing half is one-piece in design. The radially designed crush ribs 57 are shown in further detail in FIG. 3.

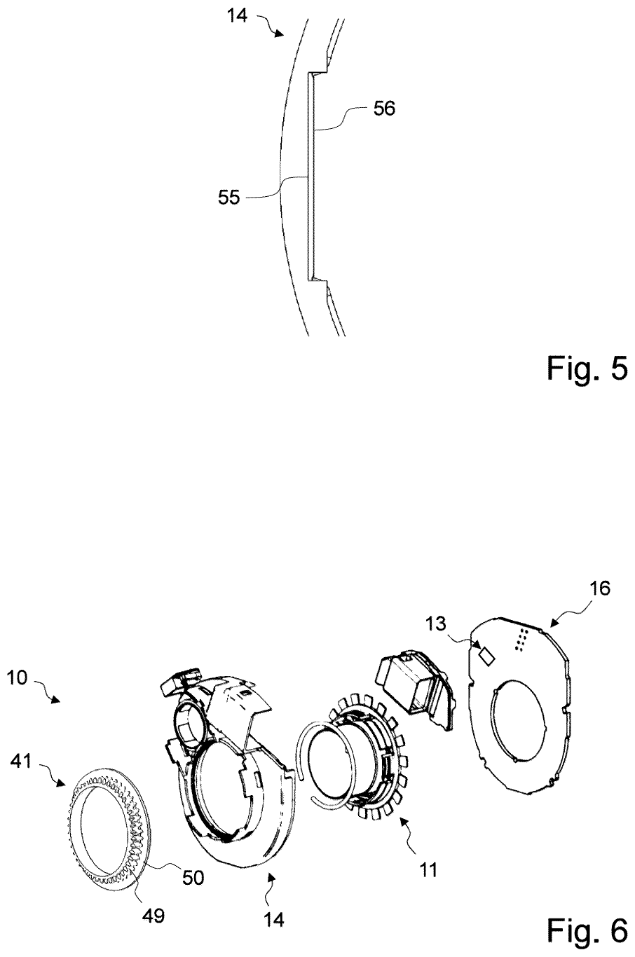

FIG. 4 shows the printed circuit board 16 after it has been inserted in a housing volume defined by the housing 14 or placed on the housing. The above-described clamped connection between the clamp 51 and the mating clamp 52 is produced in this process. In FIG. 5, the clamped connection of the clamping projection 56 in the clamping recess 55 is shown in further detail.

FIG. 6 shows an exploded view of the above-described structural components that are used for producing the rotational angle sensor unit. Shown in FIG. 6 in addition to the housing 14, the rotor 11, and the printed circuit board 16, is also a gearwheel 41, which has a gear region 49 and a flange region 50. Furthermore shown in FIG. 6 is a stator 13 that is attached to the printed circuit board 16.

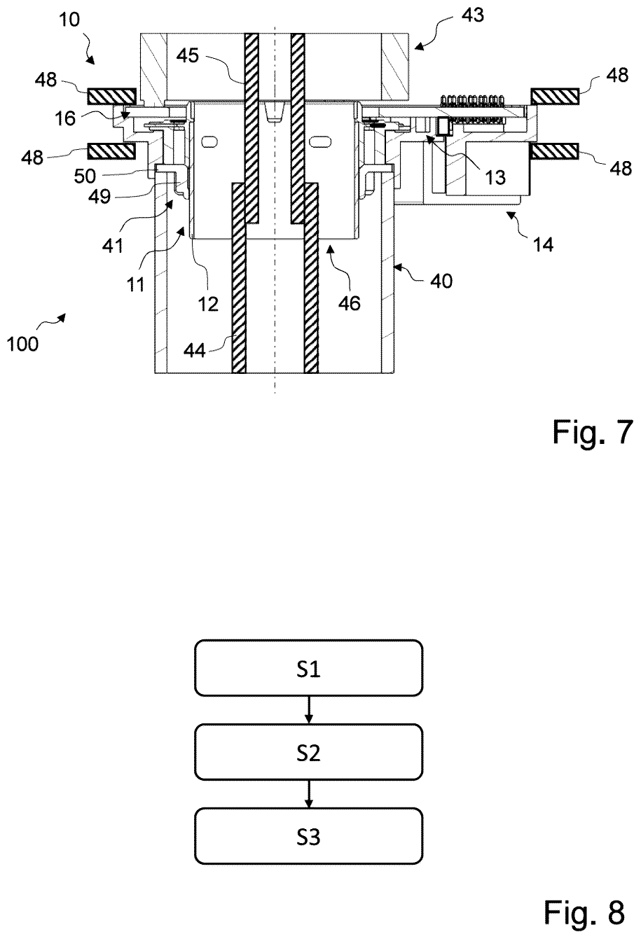

In FIG. 7, a partially completed rotational angle sensor unit is shown, in which the printed circuit board 16 is or has been positioned in the housing 14 or in the housing volume defined by the housing 14. This process step is carried out via a holding device 48, an aligning structure 40, and a positioning unit 43. The production process for producing the rotational angle sensor unit can be carried out with a system 100 partially shown in FIG. 7, wherein the system includes, in particular, the aligning structure 40 and the positioning unit 43.

The steps of the method are explained below with reference to FIG. 8 and the functional components already mentioned and shown in FIGS. 1 to 7.

In a first step S1, the aligning structure 40 is first of all provided, and positioned on the housing unit via a press fit. More precisely, the aligning structure 40 is positioned on the housing 14 and, in the process, on the flange region 50 of the gearwheel 41. In a second step S2, the housing unit with the aligning structure 40 attached thereto is held in a predefined position via the holding device 48. In this process, the housing 14 is clamped in the holding device 48. In a third step S3, the printed circuit board 16 is now positioned in the housing volume via the positioning unit 43, wherein the positioning unit 43 is moved with respect to the position of the aligning structure 40 that is positioned in the housing unit in order to position the printed circuit board 16 in a predefined position relative to the rotor 11. More precisely, the aligning structure 40 has an alignment guide 44, and the positioning unit 43 has a positioning guide 45, wherein the positioning guide 45 is guided along the alignment guide 44 in order to move the positioning unit 43 with respect to the position of the aligning structure 40. The alignment guide 44 and the positioning guide 45 meanwhile are each moved through the rotor opening 46 of the rotor 11 in order to guide the positioning guide 45 along the alignment guide 44. For a maximally trouble-free sliding within one another of the alignment guide 44 and the positioning guide 45, the end regions can each have a bevel, a funnel-shaped and/or conical edge structure. The clamped connection between the clamp 51 and the mating clamp 52 is produced while the positioning guide 45 is guided along the alignment guide 44 in order to position the printed circuit board 16 in the housing volume.

The invention allows for additional design principles apart from the embodiments shown. In other words, the invention should not be viewed as being limited to the exemplary embodiments explained with reference to the figures.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for producing a rotational angle sensor unit comprising a housing unit with a housing that defines a housing volume, a rotor that is at least partly positioned in the housing volume, a gearwheel adapted to be rotated by the rotor, and a printed circuit board that is positioned in the housing volume, the method comprising:
providing an aligning structure;
positioning the aligning structure on the housing unit; and
positioning the printed circuit board in the housing volume via a positioning unit, the positioning unit being moved with respect to a position of the aligning structure positioned on the housing unit in order to position the printed circuit board in a predefined position relative to the rotor.

2. The method according to claim 1, wherein the aligning structure has an alignment guide and the positioning unit has a positioning guide, and wherein the positioning guide is guided along the alignment guide in order to move the positioning unit with respect to the position of the aligning structure.

3. The method according to claim 2, wherein the alignment guide and the positioning guide are each moved through a rotor opening of the rotor and/or a projection of the rotor opening to guide the positioning guide along the alignment guide.

4. The method according to claim 1, wherein the aligning structure is positioned on the housing unit via a press fit.

5. The method according to claim 1, wherein, during the positioning of the printed circuit board in the housing volume, the housing is held in a predefined position by a holding device attached to the housing.

6. The method according to claim 1, wherein the gearwheel has a gear region and a flange region, and wherein the aligning structure is positioned on the flange region.

7. The method according to claim 1, wherein the housing unit has a clamp and the printed circuit board has a mating clamp, and wherein the printed circuit board is positioned in the housing volume via a clamped connection between the clamp and the mating clamp.

8. The method according to claim 7, wherein the clamped connection between the clamp and the mating clamp is produced while the positioning guide is guided along the alignment guide in order to position the printed circuit board in the housing volume.

9. A system to produce a rotational angle sensor unit via the method according to claim 1, the system comprising the aligning structure and the positioning unit, wherein the aligning structure has the alignment guide and the positioning unit has the positioning guide in order to move the positioning unit along the alignment guide with respect to the position of the aligning structure.

10. The system according to claim 9, further comprising a holding device for holding the housing in a predefined position during the positioning of the printed circuit board.

11. A housing for producing a rotational angle sensor unit via the method according to claim 1, the housing comprising a clamp to provide a clamped connection with a mating clamp of the printed circuit board.

12. The housing according to claim 11, wherein the clamp has at least one clamping peg to produce a clamped connection with a corresponding clamping opening of the mating clamp of the printed circuit board and at least one clamping recess to produce a clamped connection with a corresponding clamping projection.

13. The housing according to claim 12, wherein lateral crush ribs project from an outer circumferential surface of the clamping peg to provide the clamped connection with the clamping opening of the mating clamp.

14. The housing according to claim 11, wherein the housing is formed as one-piece and/or monolithic.

15. A printed circuit board to produce a rotational angle sensor unit via the method according to claim 1, via a housing, a mating clamp with at least one clamping opening and a clamping projection, wherein the clamping projection extends from an edge region of the printed circuit board orthogonally to an opening direction of the at least one clamping opening.
